(19) United States
(12) Patent Application Publication
(10) Pub. No.: US 2008/0129256 A1
(43) Pub. Date: Jun. 5, 2008

(54) VOLTAGE REGULATOR MADE OF HIGH VOLTAGE TRANSISTORS

(75) Inventors: Michele La Placa, Cefalu (IT); Ignazio Martines, Tremestieri Etneo (IT)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics S.r.I., Agrate Brianze (MI) (IT)

(21) Appl. No.: 11/949,517

(22) Filed: Dec. 3, 2007

(30) Foreign Application Priority Data
Dec. 5, 2006 (IT) VA2006A000071

(51) Int. Cl. G05F 1/10; G11C 16/06

(52) U.S. Cl. 323/234; 365/185.2

(57) ABSTRACT

A voltage regulator including an output stage to generate an output voltage based upon a control voltage determined as a function of a difference between a reference voltage and a voltage representative of the output voltage. A sense resistor is coupled in series with the output stage and an auxiliary power stage is coupled in parallel with the output stage and cooperates therewith to supply a load as a function of a voltage drop across the sense resistor. A scaled replica stage of the output stage is controlled by the control voltage to generate a replica voltage of the output voltage. A bias network biases the scaled replica stage and output stage with identical currents to keep constant bias voltages. The output stage, the auxiliary power stage, the scaled replica stage, and the bias network each have high voltage transistors. The bias network is input with a square-wave control signal and an externally generated boosted voltage, to bias the scaled replica stage and the output stage in conduction states with the identical currents at the externally generated boosted voltage, when the square-wave control signal is active.

### FIELD OF THE INVENTION

This invention relates to voltage regulators and particularly to an integrated voltage regulator suitable for a FLASH memory device with a reduced consumption when the memory is in a stand-by state.

### BACKGROUND OF THE INVENTION

The ever increasing scaling down of the size of integrated devices is leading to the realization of more compact and faster devices with reduced power consumption figures. These devices work typically with a supply voltage lower than that (3.3V) traditionally required for CMOS technology devices.

Modern 0.13 μm CMOS fabrication technologies for nonvolatile memory devices allow fast and high density chips capable of operating at a low supply voltage (1.8V), but the wide diffusion of 3V systems and interfaces is slowing down transition toward 1.8V powered devices. In order to power 1.8V devices from 3V supply lines, a voltage regulator is normally used.

In FIG. 1, two known voltage regulators are shown. They typically include an amplification stage that compares a scaled replica of the output voltage with a reference voltage VBG. These amplifiers generate a control voltage VREF of a MOSFET that is biased in a more or less deep conduction state depending on whether the voltage on the supplied load LOAD diminishes or increases.

The schemes of FIG. 1 are characterized by a negative feedback loop that includes the output stage. This requires potentially difficult compensation for obtaining an adequate stability frequency margin, thus penalizing response speed. This impairs the stability of the output voltage in the presence of fast variations of the load current.

Response speed of the feedback loop is penalized also by limitations of the consumption during stand-by and during normal functioning. These limitations make the regulators of FIG. 1 unsuitable for a NOR FLASH memory device that typically has fast varying current absorption. Moreover, the response delay when resuming from the stand-by state may penalize the access speed to stored data.

The circuits disclosed in U.S. Patent Publication No. US/2006/0186865 to Placa et al., European Patent Application Nos. EP 1667158 and EP 1653315 to Pisasale et al. and shown in FIG. 2 address these problems. A common characteristic of these circuits is that the output stage is not included in the feedback loop, with consequential improvements in terms of frequency stability and speed of response as disclosed in the article by Gerritt W. den Besten, et al., titled “Embedded 5 V-to-3.3 V Voltage Regulator for Supplying Digital IC's in 3.3 V CMOS Technology”, IEEE Journal of Solid-State Circuits. This is possible because of the presence of a “replica” stage that ensures the stability of the output voltage independently from the load current. The matching between the MOS M1-M2 of the “replica” stage and the MOS M3-M4 of the output stage allows tracking of process and temperature fluctuations, while keeping the output voltage VOUT at the desired value KVBG=VBG*(1+R″/R1). VBG is a stable reference voltage, typically generated by a band-gap generator, and it is practically insensitive to process spread, supply and temperature fluctuations.

These known circuits may ensure a slow but accurate control of the DC output voltage; therefore, the operational amplifier, that generates the signal VREF, can be biased with currents of about a 1 mA, with a negligible increase of the overall stand-by power consumption of the memory and of the voltage regulator.

The current absorbed by the memory under working conditions is supplied by the output stage b) or c). In both cases, these stages are locally fed-back, but without the above mentioned limitations of the converters of FIG. 1.

This result is possible because of particular topological/circuit choices, and because these stages are active only when the device resumes from stand-by, thus they do not worsen significantly the power consumption figures. Therefore, it is easier to obtain a fast response, appropriately limited by the filter capacitance CF (the order of magnitude of which is about 1 nF). This determines an enhanced stability of the output voltage VOUT, with a reduced ripple.

The output stages b) and c) of the circuits disclosed in U.S. Patent Publication No. US/2006/0186865 to Placa et al. and European Patent Application Nos. EP 1667158 and EP 1653315 to Pisasale et al., respectively, differ from each other because of their functioning modes: analog the first, and mixed analog-digital the second.

In the first case (FIG. 2b), the LV (Low Voltage) natural N-channel MOS of the output power stage is controlled by a continuous analog signal that is a function of the voltage drop on a sense resistor Rsense proportional to the output voltage variation due to the varying current absorption by the load.

In the second case (FIG. 2c), a dynamic modulation of the channel width of the output power stage, that is a LV natural N-channel transistor controlled with a constant gate voltage VREF, is actuated. Modulation is based on an analog-to-digital conversion of the results of comparisons of the output voltage with three voltage references. The so-called “bidirectional domino” enabling of the portions in which the output transistor is subdivided, enhances accuracy allowing a finer control of the output voltage.

The use of the so-called Low Voltage (LV) transistors, characterized by gate oxide thickness of about 3.5-4.0 nm, may impose an upper limit of about 4.2V of the applied external supply voltage. In order to prevent failure in the event of excessively high externally applied voltages, protection circuits for absorbing the external voltage that exceeds the limit are needed.

The protection circuits may include High Voltage (HV) transistors, with 16 nm gate oxides and, as a consequence, with a gain reduced by one fourth compared to the gain of the LV MOS. These transistors, connected in series to the circuit to be protected, deliver all the current absorbed by the load of the converter and thus may be desirably relatively large for avoiding relevant voltage drops that would negatively influence the regulation of the voltage VOUT, especially when the output voltage is at or close to the minimum value of the supply range. In the analyzed cases, the required overall channel width for the HV protection MOS was comparable with that of the LV MOS to be protected, with a consequential significant overall silicon area occupation.

Another characteristic of the circuits of FIG. 2 is that the transistors M2, M4 and the (N-channel) output power transistors are Low-Voltage natural transistors, that is they have a low threshold voltage. These transistors are used whenever an extended functioning range of the external voltage up to 2.4V is required without requiring boosting of the gate voltages VB1 and VB2.

### SUMMARY OF THE INVENTION

A voltage regulator that may be advantageously made entirely with High Voltage transistors with substantially identical power consumption to that of the above discussed regulators of the prior art has been found.

As many of the known voltage regulators, the regulator of this invention also comprises a first stage that generates the desired voltage and a second stage that replicates this voltage on an output node of the regulator.

A characteristic of the regulator is that all employed transistors are High Voltage transistors and that a bias network of the two stages supplies, under stand-by conditions, a current at a boosted voltage only in correspondence to the active state of an externally generated square wave signal. The duty cycle of the square wave signal is such that the bias network keeps constant the bias voltages of the two stages. In this way, the voltage on the output node of the regulator remains practically constant and power consumption during stand-by is substantially reduced. Preferably, the two stages are both source followers.

The voltage regulator is suitable for being integrated in a memory device, particularly a FLASH NOR memory. In this case, the boosted voltage used by the bias network is supplied by the charge pump generator of the memory that generates the read voltage of the cells.

The voltage regulator further comprises an auxiliary power stage controlled by the voltage drop on a sense resistance in series to the load of the regulator, that cooperates with the source follower stage for contributing with the latter in supplying the load. According to the preferred embodiment, the auxiliary power stage includes a plurality of identical modules connected in parallel. Each module may comprise a signal path suitable for generating a current representative of the voltage on the sense resistor, and a comparator having a resistive input network, the total resistance of which is established by at least a control voltage, connected to the path such that the representative current flows therethrough, the comparator generating a high logic signal when the voltage on the resistive network exceeds a pre-established threshold. Each module further comprises a control stage suitable for supplying a pre-established current when the logic signal is high and the regulator is not in a stand-by condition. The control voltage(s) of each comparator is chosen among the voltage of a common ground node and those of logic signals generated by other comparators.

Substantially, the auxiliary power stage may be a current generator controlled by an externally generated voltage, that may be useful also in circuits different from the voltage regulator requiring controlled contributory approaches of current supply.

### BRIEF DESCRIPTION OF THE DRAWINGS

FIGS. 1a and 1b depict known voltage regulators according to the prior art.

FIGS. 2a, 2b and 2c depict voltage regulators of the above mentioned prior patent applications.

FIG. 3 depicts a basic architecture of a voltage regulator according to this invention.

FIG. 4 shows an embodiment of the bias network of the voltage regulator, and of the related control signals, according to the present invention.

FIG. 5 depicts an architecture of the auxiliary power stage employed in the voltage regulator according to this invention.

FIG. 6 is a time diagram of the load current and of the load voltage, according to the present invention.

FIG. 7 shows how to switch the load switches depicted in FIG. 5 for obtaining a quasi-linear control characteristic.

FIG. 8 illustrates in detail a module of a multi-module auxiliary power stage according to the present invention.

FIG. 9 depicts an auxiliary power stage having a modular architecture in accordance with the present invention.

FIGS. 10 and 11 are time diagrams of simulations of the regulator of FIG. 5 for linear and quasi-linear control characteristics.

FIG. 12 shows sample waveforms of the output voltage of the regulator of FIG. 5 during a read operation of a datum from a memory array.

### DETAILED DESCRIPTION OF THE PREFERRED EMBODIMENTS

An embodiment of the voltage regulator of this invention is depicted in FIG. 3. The voltage regulator is particularly suitable for use in NOR FLASH memory devices and according to an embodiment is made with only HV enhancement transistors. As will become clearer hereinafter, the voltage regulator does not increase the area requirements and does not negatively affect performances. The pre-charge circuits commonly employed for starting up the regulator have been omitted for better focusing on the aspects of the embodiment.

The meaning of the main signals of FIG. 3 is defined in the following Table:

| VBG | Reference voltage |
|---|---|
| TDB | Square-wave signal for |
| | keeping constant the bias |
| | of the source follower |
| | stage |
| SBY_N | Stand-by signal |
| VXR | Boosted read voltage |

At least for the portion dedicated to regulate the output voltage, the circuit has a circuit block that “replicates” the desired output voltage. The voltage replicating circuit has a double source follower (M1, M2) configuration, as the corresponding circuit block (M3, M4). This minimizes disturbances induced by output fluctuations on the node VREF, because the capacitive coupling is obtained by the two overlap capacitances connected in series with the transistors M3 and M4. Disturbances are reduced also because of the double filtering action of the capacitors C1 and C3, as in the known circuit disclosed in European Patent Application No. EP 1667158 to Pisasale et al.

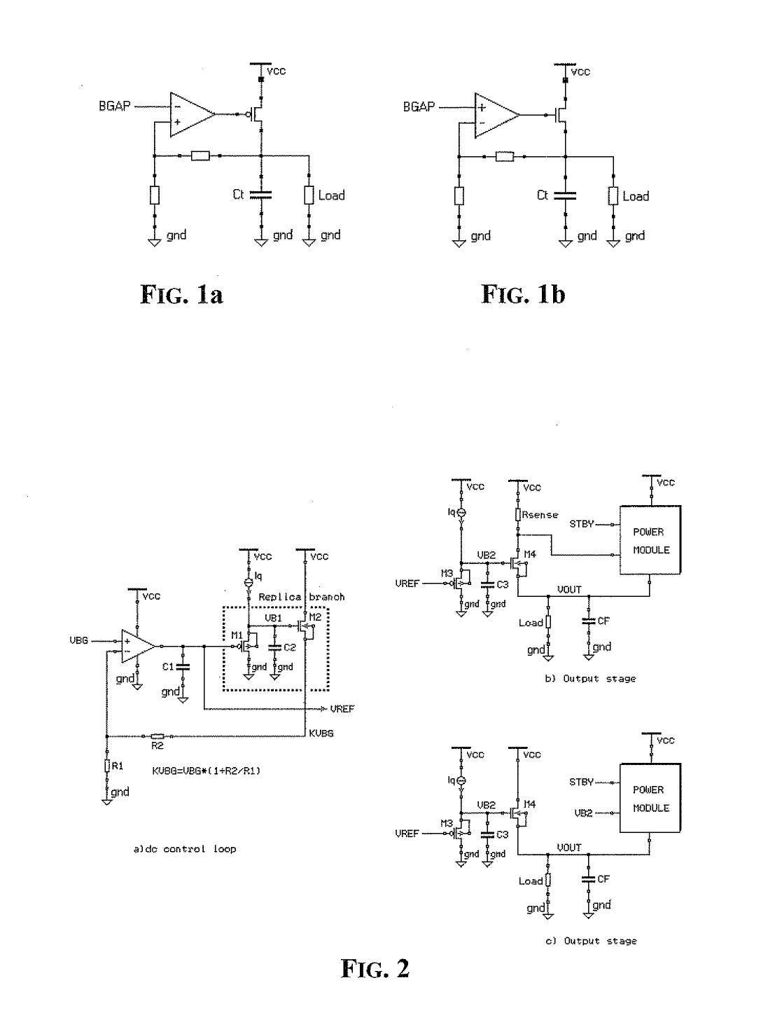

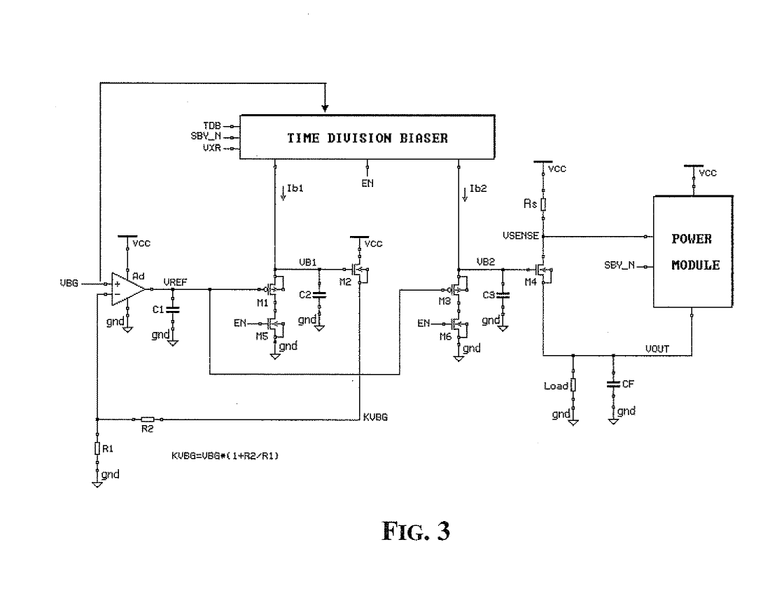

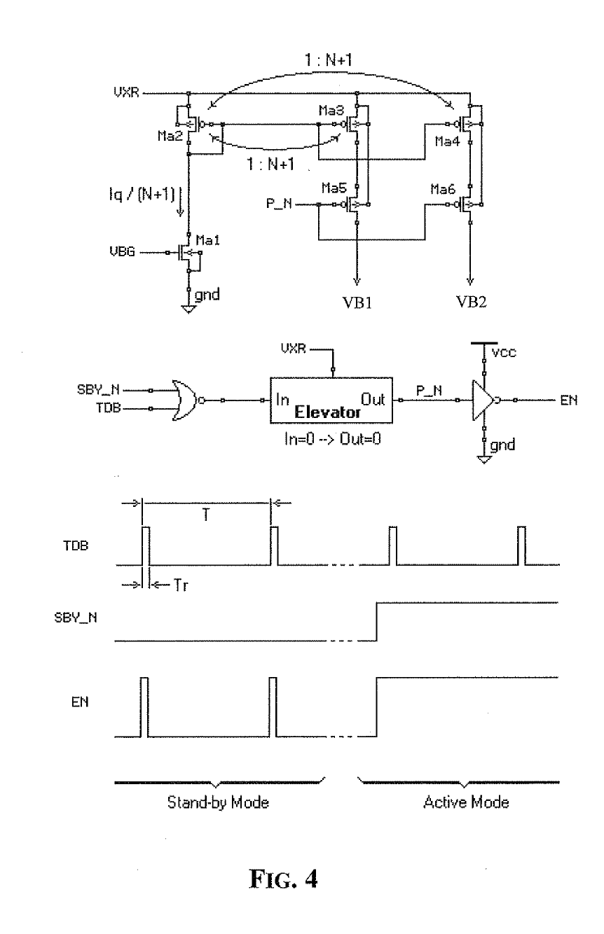

Similarly to the prior art circuits of FIGS. 2a), 2b) and 2c), a control circuit generates the voltage VREF and a sense resistor Rs is connected to the drain of the NMOS M4. A mixed analog-digital power block POWER MODULE may be used as in the prior art circuit of FIG. 2c), or it may have a particularly efficient structure as will be disclosed hereinafter.

The block TIME DIVISION BIASER generates the bias currents Ib1 and Ib2 of the source followers M1 and M3. The fact that there are no natural transistors implies that the gate voltages of the NMOS M2 and M4 should be boosted.

FLASH memory devices normally include charge pump generators, for example, the charge pump generator that supplies the read voltage VXR. This voltage, typically of about 4.5V, is always available, both in stand-by conditions as well typically as in working conditions. Generating boosted voltages requires an increased power consumption ideally multiplied by N+1, being N the number of stages connected in series in the charge pump generator.

Even if it would appear impossible to use only HV transistors without increasing significantly power consumption figures, investigations carried out by the applicant showed that this outstanding result can be attained because the output voltage replicating network and its corresponding output network in a double follower configuration can be biased through a time division biasing network TIME DIVISION BIASER, as the one depicted in FIG. 4.

The MOS Mal that has the reference voltage VBG applied to its gate, generates the current Iq/(N+1). This current is multiplied by the MOS Ma3 and Ma4 by a multiplication factor (N+1) and is supplied to the source followers M1 and M3 through the switches Ma5 and Ma6, controlled by the signal P_N. The N-channel MOS M5 and M6 (FIG. 3) are controlled by the signal EN.

The signals P_N and EN are logically opposite to each other, but have a different high logic level: the signal P_N is obtained by level shifting from VOUT to the voltage VXR, wherein VOUT is the regulated output voltage, whilst the high logic level of EN is that of the external supply voltage Vcc.

The signal P_N depends on the signal TDB, that has a duty cycle of:

d=Tr/T=[k(N+1)]−1 k>1 (1)

The transistors Ma3 and Ma4 supply a mean bias current d*Iq. The average current consumption of the charge pump VXR is:

$$\begin{matrix}Ip = I ( Ma 1 ) + avg [ I ( Ma 3 ) ] + avg [ I ( Ma 4 ) ] \\ = Iq / ( N + 1 ) + 2 d Iq \\ = [ Iq / ( N + 1 ) ] ( 1 + 2 / k ) ;\end{matrix} \qquad ( 2 )$$

avg[.] being the function that calculates the mean value of its argument, and the increment of the current absorbed by the Vcc is:

(N+1)Ip=(1+2/k)Iq. (3)

For example, for k=2 the current absorbed by the supply is 2Iq instead of (2N+3)Iq, N being an integer number chosen in the set {2, 3, 4, 5}. Thanks to the time division biasing, stand-by power consumptions are reduced.

When TDB=low the signal EN is grounded (GND), the NMOS switches M5 and M6 (FIG. 3) are off and the voltage levels VB1 and VB2 on the gates of M2 and M4, respectively, are held by the capacitors C2 and C3.

In working conditions, being SBY_N=high, the transistors Ma5, Ma6, M5 and M6 are always on, both because there are not stringent consumption constraints and the DC bias makes the circuit more robust against disturbances due to eventual (capacitive) coupling with other signals.

According to a non-essential, though preferred, embodiment the output power block POWER MODULE may have a particularly efficient modular architecture. FIG. 5 shows the basic architecture of the block in the form of an array of n current generators Iᵢ each connected in series with a switch Swi having a threshold voltage Vti>Vti−1.

According to such a preferred embodiment of the voltage regulator of this invention, the MOS M4 has a double function. It controls the DC component of the output voltage VOUT and it amplifies dynamically eventual voltage reductions of the output voltage VOUT on the output filter capacitor CF due to current absorption surges by the load that increase the drain current, incrementing of the voltage drop on the sense resistor Rs.

Consequently, all switches the threshold voltage of which is Vt<(Vcc−VSENSE) are on, thus allowing the respective generators of the array to supply current for restoring the charge extracted from the capacitor CF and restoring the output voltage VOUT to the correct level.

Each current generator contributed to the current delivered to the load in on-off mode. Assuming that the load absorbs a constant current I_{Load} such that:

$${I}_{a} = {\sum }_{k = 1}^{i - 1} {I}_{k} \leq {I}_{load} \leq {\sum }_{k = 1}^{i} {I}_{k} = {I}_{b} i = 1 , 2 , … , n \qquad ( 4 )$$

in this condition, the switches Swk (k=1, 2, . . . , i−1) are always on.

Let us suppose that the drain current of M4 is negligible with respect to I_{Load} In a time interval in which the i-th switch Swi is open, the currents will be

Iₐ<I_{Load}

and the capacitor CF discharges itself with a constant current ΔIcd=I_{Load}−Iₐ.

The output voltage VOUT decreases, the drain current of M4 increases as far as the voltage drop on the sense resistor Rs surpasses the threshold voltage of the i-th switch Swi. When this switch is turned on, the currents will be

I_{b}>I^{Load}

and the capacitor charges itself with a constant current

ΔIcc=I_{b}−I_{Load}.

The output voltage Vout increases according to a slope waveform, the drain current of M4 and also the voltage drop on the resistor Rs diminish. When the voltage drop on the sense resistor becomes smaller than the threshold voltage of the switch Swi, this switch turns off and a next cycle starts.

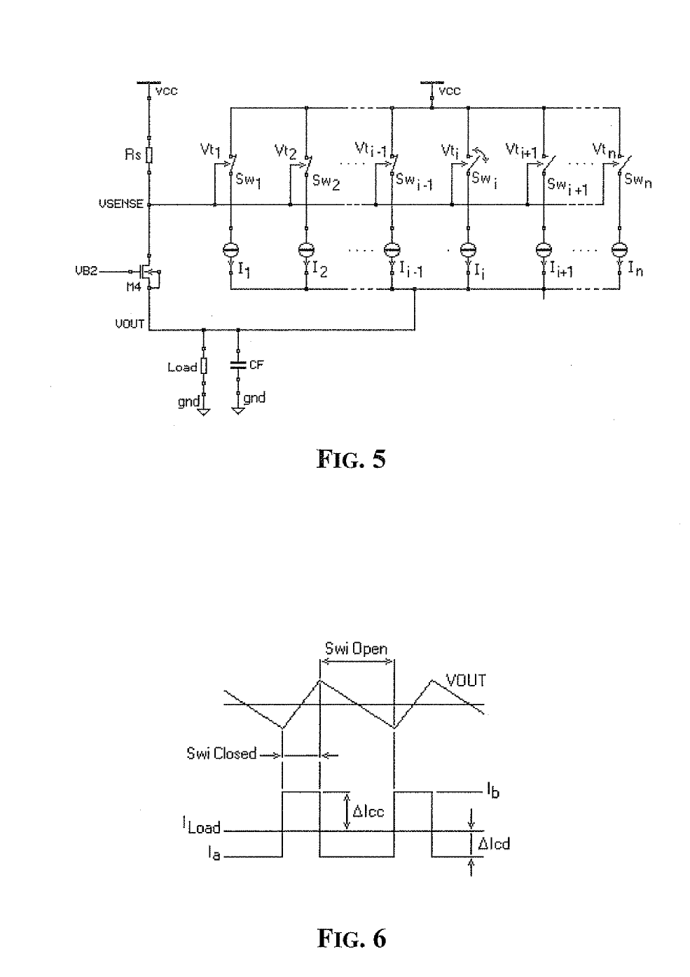

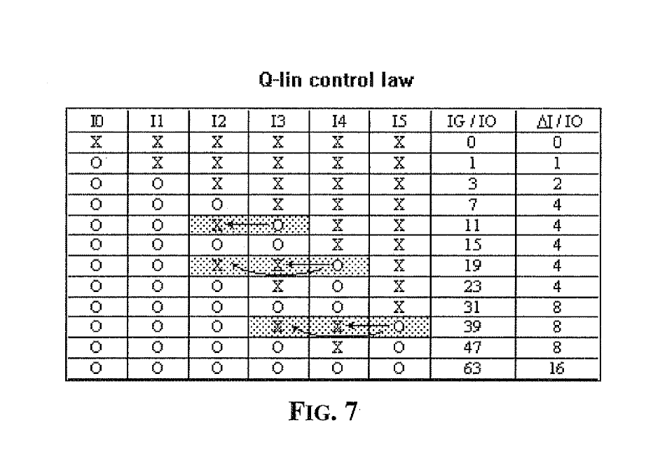

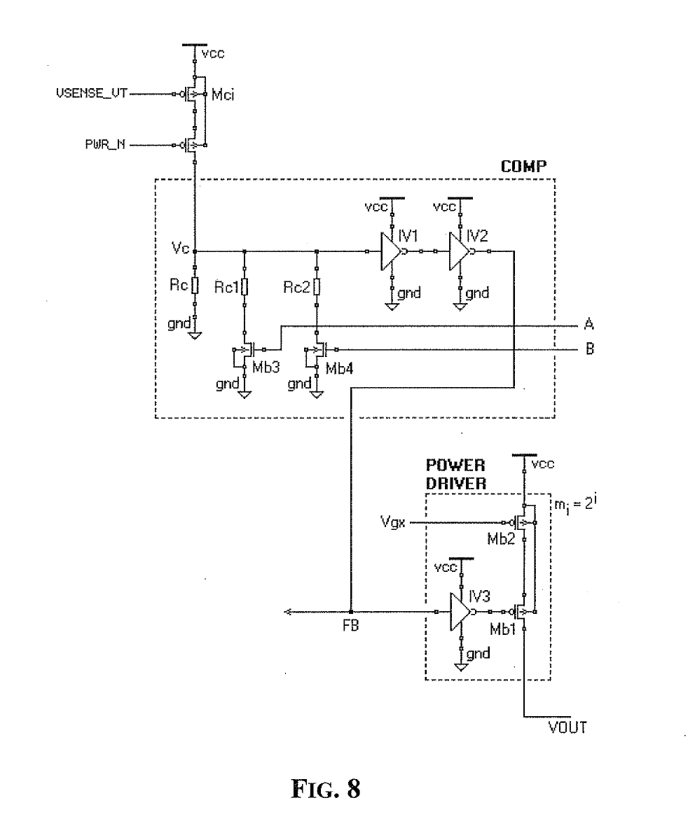

The waveforms of the output voltage VOUT and of the current supplied by current generators are depicted in FIG. 6.

The amplitude of the ripple Vri is proportional to

$$\frac{{τ}_{i}}{{C}_{F}} {I}_{i} i = 1 , 2 , … , n \qquad ( 5 )$$

wherein τᵢ is the turn on/turn off delay of the switch Swi.

In order to minimize the ripple, in view of equation (5) it is desirable to opt for a large number n of current generators. Being I_{TOT} the current supplied with all switches on, the current Iᵢ of the i-th generator will be

$${I}_{i} = \frac{{I}_{TOT}}{n} \qquad ( 6 )$$

In this case, the current supplied by the POWER MODULE block varies according to a linear discrete (uniform stepwise) control law:

$${I}_{g} = \frac{{I}_{TOT}}{n} i i = 1 , 2 , … , n \qquad ( 7 )$$

and the ripple amplitude remains constant while the supplied current varies.

Preferably, the control input node of each current generator (FIG. 9) has a capacitance Ci that charges the node VSENSE. If n increases, also the overall capacitance increases, the response speed of the feedback loop slows down and the delay τᵢ increases. Therefore, for a certain design I_{TOT}, the number of generators n should be chosen to minimize the product τᵢ*Iᵢ.

Depending on the current absorption characteristics of the load, different and more specifically suitable control laws or algorithms may be implemented.

As already said, NOR FLASH memory devices are characterized by short pulse current absorptions, with peak values often larger than 100 mA, but with a mean value of just about 10 mA. The current peaks are due to switchings of digital circuits and of charge pumps.

By contrast, analog circuits, relatively more sensitive to supply ripples, typically absorb moderately varying currents about a certain mean value. The regulated voltage converter should have a limited ripple when supplying relatively small currents, and at the same time it should possess an appropriate DC “driving capability” for ensuring a fast recovering of the charge lost by the filter capacitor CF upon absorption of a current pulse by the load.

It has been found that in these applications the converter may be designed for supplying a DC current I_{TOT} of about 3-4 times the value of the typical mean power consumption of the memory, preferably implementing an exponential type control law:

Iᵢ=Io2ⁱ i=0, 1, . . . , p (8)

In this way, a non-uniform stepwise function is obtained that allows lower steps at low current absorption and higher steps at large current absorption. Overall, the ripple will be reduced for supplied currents in the neighborhood of the mean absorption of the memory.

Being

p+1<n

there are the advantages due to a reduced number of current generators (and related circuitry) and a shorter delay time τᵢ.

In the hypothesis that the currents supplied by the current generators be determined according to the exponential progression defined by equation (8), a further reduction of the ripple may be obtained by acting on the thresholds of the connecting switches by introducing feedback loops.

Let us consider two generic switches Swk and Swj, being k<j≦p, with thresholds Vtk and Vtj, respectively, and let us suppose that Vtk<Vtj. The voltage drop on the nodes of the resistor Rs ranges between Vtk and Vtj, thus Swk is on and Swj is off. When the voltage on the nodes of the sense resistor is larger than Vtj, the switch Swj turns on and through the feedback loop the threshold of Swk is incremented to the value Vtk′>Vtj, thus opening it. The switch Swk will turn on when the voltage on the nodes of Rs will surpass the new threshold voltage Vtk′.

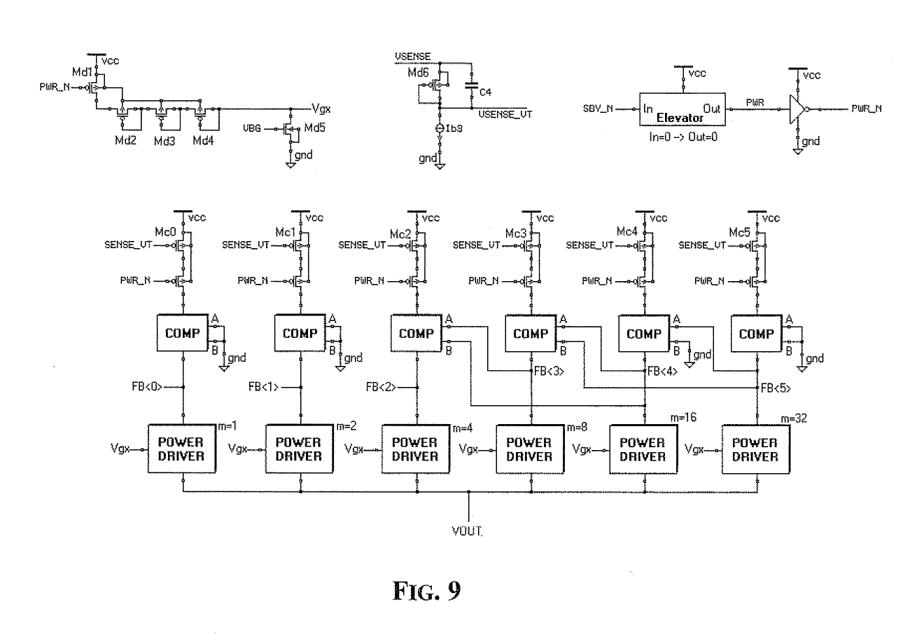

For sake of illustration, for p=5, all possible states of the switches (“o” on, “x” off) are listed in the table of FIG. 7 and the “direction” of the feedback from certain switches towards one or two switches of a lower threshold is also indicated (in general there may be more than two switches, that is the feedback may be carried out by the i-th generator towards the generator i−k, k≧3). In the last two columns of the table are indicated the overall current Ig and the variation steps ΔI of the supplied current, referred to the basic current Io. The amplitude of the initial steps is limited and, in particular, it is constant up to about one third of the maximum current. This characteristic is analogous to that obtainable with a linear control law (ΔI=4), but by using only 6 current generators instead of I_{TOT}/ΔI=63/4≈16.

The feedbacks allow establishing the control law by surreptitiously introducing steps of limited amplitude for obtaining a particular control law, hereinafter referred as “Q-lin” (Quasi-linear). Having so minimized both the number of current generators as well as the amplitude of current steps, the product τᵢ*Iᵢ in the ripple equation (5) is minimized.

The bonus of the further decrease of the ripple resulting from the introduction of feedbacks could be spent for reducing the value of the filter capacitance CF, that is of the most cumbersome component (over 50% of the overall area), if ripple specifications were already met without introducing feedbacks.

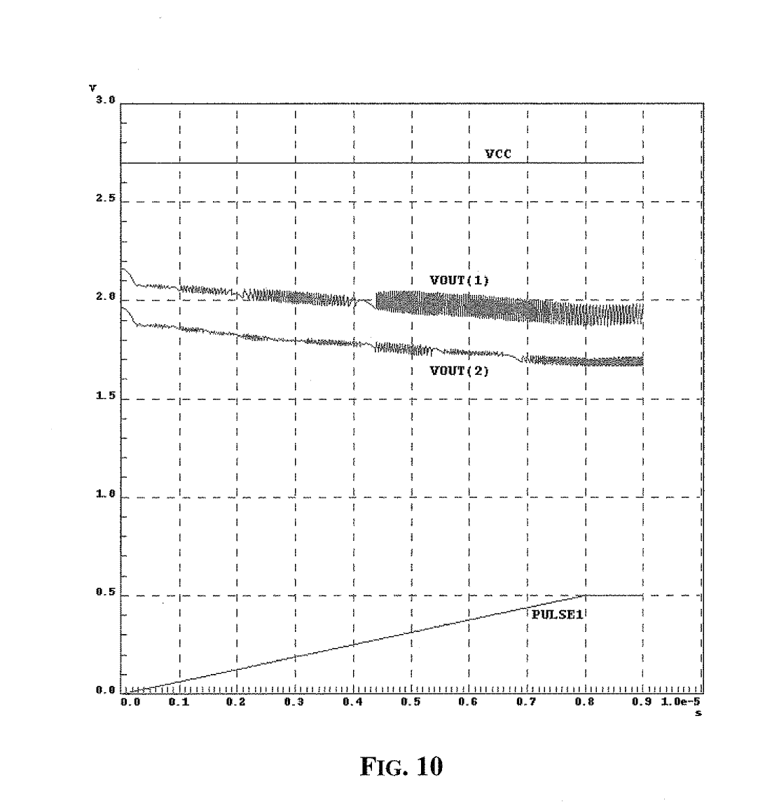

A circuit embodiment of the power module implementing the just illustrated Q-lin control law is described hereinafter. A circuit diagram of a module of a current generator of this invention is shown in FIG. 8.

The PMOS Mb2, that functions as a current generator, and the PMOS Mb1, that functions as a switch controlled by the inverted replica of the signal FB, are observable within the dash line perimeter of the block POWER DRIVER. How the gate signal Vgx it is generated will now be described.

The multiplicity of the i-th power driver is indicated with mᵢ=2i, being i=0, 1, . . . , p. The signal VSENSE_VT on the gate of the PMOS Mci, i=0, 1, . . . , p is obtained by the signal VSENSE through a level shift equal to about a threshold voltage of a PMOS. Therefore, the Mci overdrive equals the voltage drop Vs on the nodes of the sense resistor Rs.

Suppose that the signals A and B and the enabling signal PWR_N are grounded. The signal FB assumes a high logic value when the signal Vc overcomes the switching threshold Vx of the inverter IV1. This happens because the drain current of the PMOS Mci overcomes the value:

Idx=Vx/Rc (9)

that is when:

$$Vs > Vt = \sqrt{\frac{Vx}{Kp ( \frac{W}{L} ) Rc}} \qquad ( 10 )$$

The current generator is active when the voltage Vs on the nodes of the sense resistor Rs overcomes the threshold voltage Vt. From equation (10), it is observed that the threshold Vt increases if the channel width W of Mci decreases or if the resistance Rc decreases.

According to a preferred embodiment, a “natural” threshold Vt (with A and B grounded) is fixed by acting on the width parameter W, and the resistance connected to the node Vc has been exploited for modifying the threshold of the generator in presence of at least one of the feedback inputs A, B at high logic level (of course the number of feedback inputs may be more than two). It is worth highlighting that the resistor Rc can be substituted by a current generator of value Vx/Rc for the same function.

A more detailed circuit architecture of the power module is depicted in FIG. 9, that is substantially a current generator, according to the preferred embodiment. The power drivers have multiplicity from 1 up to 32 (p=5) and corresponding feedback paths as in FIG. 7. The enabling signal PWR_N is a high voltage (Vcc) replica of the standby signal (SBY_N) generated by the memory device.

The level shifter by which the voltage VSENSE_VT is generated is realized with the diode-connected PMOS Md6, biased with a current Ib in the order of hundreds of nA, that is negligible in respect to the overall stand-by current consumption of about 10 μA of the FLASH memory and of the voltage regulator.

The voltage Vgx is generated by subtracting a constant voltage, for example the voltage drop on three diodes, from the externally generated supply voltage Vcc. This voltage Vgx is used to impose, between the source and gate of the PMOS Mb2, a voltage that is substantially independent from the supply voltage Vcc between the source and gate of the PMOS Mb2, thus the “driving capability” of the converter does not depend on Vcc.

FIG. 10 shows results of two SPICE™ simulations with load current having a saw-tooth waveform with relatively gradual slope (from 0 to 50 mA in 8 μs, in steady state conditions), Vcc=2.7V, CF=2 nF.

The two simulations relate to the same circuit diagram, but for curve 1 the feedback inputs are grounded (exponential control law). In order to make easier the comparison, the output voltage VOUT(1) is increased by 200 mV. The curve 2 refers to the converter the power module of which uses the Q-lin control law.

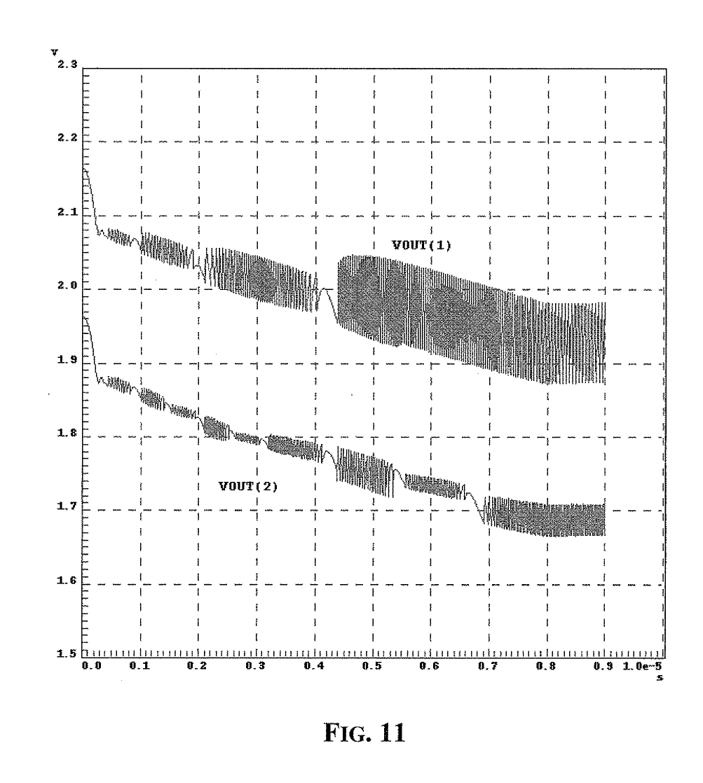

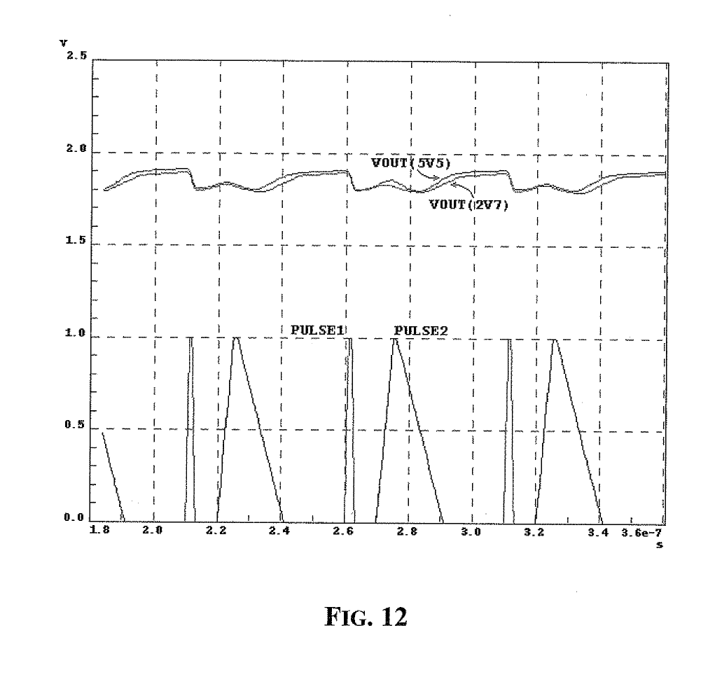

It is pointed out that the ripple is extremely reduced (±10 mV) for load currents up to about one third of the maximum value and, as desirable, is sensibly smaller than the case in which the converter works with an exponential control law (8). FIG. 11 is a magnified view of a portion of the graph of FIG. 10.

FIG. 12 depicts the waveform of the output voltage for a typical current absorption of a FLASH memory during a read operation, with a supply voltage at 2.7V and 5.5V. A sample load is realized with voltage controlled current sources (VCCS). The control signal PULSE1 drives a generator having a transconductance g1=100 mS, the control signal PULSE2 drives a generator having a transconductance g2=25 mS.

Even in this case fluctuations of the output voltage VOUT are smaller than 100 mV, independently from the external supply voltage.

The advantages of the voltage regulator are use of HV transistors only to ensure operability over a wide range of external supply voltage 3V/5V and that the occupied silicon area is comparable to that of prior art solutions that use also LV transistors because there are no protection circuits and the output power PMOS work with a larger overdrive than the output LV NMOS stages. Furthermore, the converter is suitable for processes that do not contemplate a dedicated masking step for natural transistors. This simplification of the fabrication process allows a larger fabrication throughput. The time division biasing reduces power consumption in a stand-by state (about 2 μA) within 10% of the typical power consumption of a FLASH memory, that substantially equals the power consumption of prior art regulators that use LV transistors with low threshold voltage.

Moreover, circuit implementation of the current generator is simplified for maximizing the response speed, though only HV transistors are used and the control loop of the current generators may be modified by introducing dedicated feedback loops thus introducing additional regulation steps of the output current without increasing the number of current generators. The high response speed and adoption of a Q-lin control characteristic allow an effective limitation of the ripple on the regulated voltage, or alternatively a decrement of the value of the filter capacitance CF and of the relative silicon area requirement. Additionally, current consumption under working conditions is smaller than 1 mA (about 10% of the typical current consumption of a memory) and there is negligible delay when resuming from a stand-by condition and no reduction of the speed for accessing data stored in the memory.

1-14. (canceled)

15. A voltage regulator comprising:
an output stage to generate an output voltage based upon a control voltage determined as a function of a difference between a reference voltage and a voltage representative of the output voltage;
a sense resistor coupled in series with said output stage;
an auxiliary power stage coupled in parallel with said output stage and cooperating therewith to supply a load as a function of a voltage drop across said sense resistor;
a scaled replica stage of said output stage and controlled by the control voltage to generate a replica voltage of the output voltage;
a bias network to bias said scaled replica stage and said output stage with identical currents to keep constant bias voltages;
said output stage, said auxiliary power stage, said scaled replica stage, and said bias network each comprising high voltage transistors; and
said bias network being input with a square-wave control signal and an externally generated boosted voltage, to bias said scaled replica stage and said output stage in conduction states with the identical currents at the externally generated boosted voltage, when the square-wave control signal is active.

16. The voltage regulator of claim 15, wherein said scaled replica stage and said output stage comprise respective pairs of complementary high voltage transistors, each pair being coupled in a double follower configuration.

17. The voltage regulator of claim 15, wherein said bias network is further input with a stand-by signal; and wherein said bias network comprises a plurality of switches and two current generators coupled in series respectively with said scaled replica stage and with said output stage through said switches controlled by a signal obtained as a logic combination of the stand-by signal and of the square-wave control signal.

18. The voltage regulator of claim 17, wherein said bias network comprises configuration switches coupled in series with said scaled replica stage and said output stage, and controlled by a second signal that is a logic combination of the stand-by signal and of the square-wave control signal.

19. The voltage regulator of claim 17, wherein said bias network comprises a high voltage transistor and two identical current mirrors referred to the externally generated boosted voltage, to generate amplified replicas of a reference current forced therethrough by the high voltage transistor biased at an externally generated reference voltage.

20. The voltage regulator of claim 15, wherein said auxiliary power stage is input with the voltage drop across said sense resistor and is to supply the load with a current that increases when the voltage on said sense resistor increases.

21. The voltage regulator of claim 20, wherein said auxiliary power stage comprises an enabling switch and a plurality of branches each including a current generator coupled in series with the enabling switch respectively controlled by the voltage drop across said sense resistor, the enabling switches having different threshold voltages.

22. The voltage regulator of claim 21, wherein the threshold voltages are established according to a linear control law.

23. The voltage regulator of claim 21, wherein the threshold voltages are established according to an exponential control law.

24. The voltage regulator of claim 20, wherein said auxiliary power stage comprises a plurality of identical modules coupled in parallel, each module comprising:
a signal path to generate a current representing the voltage drop across said sense resistor;
a plurality of comparators having an input resistive network, the total resistance of which is established by at least a control voltage, coupled to said signal path such that the current representing the voltage drop flows therethrough, said plurality of comparators to generate a high logic signal when the voltage on the input resistive network exceeds a pre-established threshold;
a driving stage to supply a pre-established current when the logic signal is high and said voltage regulator is not in a stand-by condition; and
the at least one control voltage of each of said plurality of comparators comprising at least one of a common ground potential and the logic signals generated by the plurality of comparators.

25. A voltage regulator according to claim 15 wherein said bias network is to be input with a stand-by signal, a square-wave control signal, and an externally generated boosted voltage, to bias said scaled replica stage and said output stage in conduction states with the identical currents at the externally generated boosted voltage, when the square-wave control signal is active and when said voltage regulator is not in a stand-by condition.

26. A voltage regulator comprising:
an output stage to generate an output voltage based upon a control voltage determined as a function of a difference between a reference voltage and a voltage representative of the output voltage;
a sense resistor coupled in series with said output stage;
an auxiliary power stage coupled in parallel with said output stage and cooperating therewith to supply a load as a function of a voltage drop across said sense resistor;
a scaled replica stage of said output stage and controlled by the control voltage to generate a replica voltage of the output voltage;
a bias network to bias said scaled replica stage and said output stage with identical currents to keep constant bias voltages;
said output stage, said auxiliary power stage, said scaled replica stage, and said bias network each comprising high voltage transistors; and
said bias network being input with a stand-by signal and an externally generated boosted voltage, to bias said scaled replica stage and said output stage in conduction states with the identical currents at the externally generated boosted voltage, when said voltage regulator is not in a stand-by condition.

27. The voltage regulator of claim 26, wherein said bias network is further input with a square-wave control signal; and wherein said bias network comprises a plurality of switches and two current generators coupled in series respectively with said scaled replica stage and with said output stage through said switches controlled by a signal obtained as a logic combination of the stand-by signal and of the square-wave control signal.

28. The voltage regulator of claim 27, wherein the bias network comprises configuration switches coupled in series with said scaled replica stage and said output stage, and controlled by a second signal that is a logic combination of the stand-by signal and of the square-wave control signal.

29. The voltage regulator of claim 27, wherein said bias network comprises a high voltage transistor and two identical current mirrors referred to the externally generated boosted voltage, to generate amplified replicas of a reference current forced therethrough by the high voltage transistor biased at an externally generated reference voltage.

30. The voltage regulator of claim 26, wherein said scaled replica stage and said output stage comprise respective pairs of complementary high voltage transistors, each pair being electrically coupled in a double follower configuration.

31. The voltage regulator of claim 26, wherein said auxiliary power stage is input with the voltage drop across said sense resistor and is to supply the load with a current that increases when the voltage on said sense resistor increases.

32. The voltage regulator of claim 31, wherein said auxiliary power stage comprises an enabling switch and a plurality of branches each including a current generator coupled in series with the enabling switch respectively controlled by the voltage drop across said sense resistor, the enabling switches having different threshold voltages.

33. The voltage regulator of claim 32, wherein the threshold voltages are established according to a linear control law.

34. The voltage regulator of claim 32, wherein the threshold voltages are established according to an exponential control law.

35. The voltage regulator of claim 31, wherein said auxiliary power stage comprises a plurality of identical modules coupled in parallel, each module comprising:
a signal path to generate a current representing the voltage drop across said sense resistor;
a plurality of comparators having an input resistive network, the total resistance of which is established by at least a control voltage, coupled to said signal path so that the current representing the voltage drop flows therethrough, said plurality of comparators to generate a high logic signal when the voltage on the input resistive network exceeds a pre-established threshold;
a driving stage to supply a pre-established current when the logic signal is high and said voltage regulator is not in a stand-by condition; and
the at least one control voltage of each of said plurality of comparators comprising at least one of a common ground potential and the logic signals generated by the plurality of comparators.

36. A power stage to supply to a load a current that increases when an input voltage increases comprising a plurality of identical modules coupled in parallel, each of the plurality of identical modules comprising:
a signal path to generate a current representative of the input voltage;
a plurality of comparators including a resistive input network, a total resistance of which is established by at least one control voltage, coupled to said signal path such that the current representative of the input voltage flows therethrough, said plurality of comparators to generate a first logic signal whenever a voltage on the input resistive network exceeds a threshold;
a driving stage to supply a current based upon the first logic signal; and
the at least one control voltage of each of said plurality of comparators being at least one of a common ground potential and voltage levels of logic signals generated by the plurality of comparators.

37. The power stage of claim 36, wherein a resistance of each resistive input network is fixed by two control voltages both control voltages of a first module being the common ground potential, both control voltages of a second module being the voltage level of the logic signal generated by the first module and the common ground potential, both control voltages of a third module being the logic signals generated by the first and the second module.

38. A FLASH NOR memory device comprising:
at least one FLASH NOR memory array;
a voltage regulator coupled to said at least one FLASH NOR memory array and comprising
an output stage to generate an output voltage based upon a control voltage determined as a function of a difference between a reference voltage and a voltage representative of the output voltage,
a sense resistor coupled in series with said output stage,
an auxiliary power stage coupled in parallel with said output stage and cooperating therewith to supply a load as a function of a voltage drop across said sense resistor,
a scaled replica stage of said output stage and controlled by the control voltage to generate a replica voltage of the output voltage,
a bias network to bias said scaled replica stage and said output stage with identical currents to keep constant bias voltages,
said output stage, said auxiliary power stage, said scaled replica stage, and said bias network each comprising high voltage transistors, and
said bias network being input with a stand-by signal, a square-wave control signal, and an externally generated boosted voltage, to bias said scaled replica stage and said output stage in conduction states with the identical currents at the externally generated boosted voltage, when said voltage regulator is not in a stand-by condition or when the square-wave control signal is active.

39. The memory device of claim 38 further comprising a charge pump generator that provides the externally generated boosted voltage.

40. The memory device of claim 38, wherein said scaled replica stage and said output stage comprise respective pairs of complementary high voltage transistors, each pair being coupled in a double follower configuration.

41. The memory device of claim 38, wherein said bias network comprises a plurality of switches, and two current generators coupled in series respectively with said scaled replica stage and with said output stage through said switches controlled by a signal obtained as a logic combination of the stand-by signal and of the square-wave control signal.

42. A method for voltage regulation comprising:
controlling an output stage by a control voltage determined as a function of a difference between a reference voltage and a voltage representative of an output voltage;
supplying a load coupled to a voltage regulator as a function of a voltage drop across a sense resistor by connecting an auxiliary power stage in parallel to the output stage;
generating a replica voltage of the output voltage of the voltage regulator using a scaled replica stage of the output stage being controlled by the control voltage;
biasing the scaled replica stage and the output stage with identical currents to keep constant bias voltages;
inputting a stand-by signal, a square-wave control signal, and an externally generated boosted voltage, to bias in a conduction state the scaled replica stage and the output stage with the identical currents at the externally generated boosted voltage, when the square wave control signal is active or when the voltage regulator is not in a stand-by condition; and
the transistors of the voltage regulator comprising high voltage transistors.

43. The method of claim 42, wherein the scaled replica stage and the output stage comprise respective pairs of complementary high voltage transistors, each pair being coupled in a double follower configuration.

44. The method of claim 42, wherein the biasing uses a plurality of switches and two current generators coupled in series respectively with the scaled replica stage and with the output stage through the switches controlled by a signal obtained as a logic combination of the stand-by signal and of the square-wave control signal.

45. The method of claim 44, wherein the biasing uses configuration switches coupled in series to the scaled replica stage and to the output stage, controlled by a second signal that is a logic combination of the stand-by signal and of the square-wave control signal.
